(19) United States
(12) Patent Application Publication
(10) Pub. No.: US 2025/0226180 A1
(43) Pub. Date: Jul. 10, 2025

(54) Plasma Treatment Device and Plasma Treatment Method

(71) Applicant: Tokyo Electron Limited, Tokyo (JP)

(72) Inventor: Hiroshi OTOMO, Yamanashi (JP)

(21) Appl. No.: 19/094,599

(22) Filed: Mar. 28, 2025

Related U.S. Application Data
(63) Continuation of application No. PCT/JP2023/031707, filed on Aug. 31, 2023.

(30) Foreign Application Priority Data
Oct. 11, 2022 (JP) 2022-163133

(51) Int. Cl. H01J 37/32

(52) U.S. Cl. CPC H01J 37/32155; H01J 37/32174; H01J 37/32541; H01J 37/32981; H01J 2237/332

(57) ABSTRACT

A plasma processing apparatus, comprising: a processing chamber; a gas supply part; a first electrode and a second electrode facing each other; first and second high-frequency power supply for supplying high-frequency powers to the first and second electrodes; a sensor part for measuring a state of plasma in the processing chamber; and a controller, wherein the first electrode applies a high-frequency voltage to generate the plasma from the processing gas, the second high-frequency power supply is a broadband power supply that is capable of setting a frequency of the high-frequency power supplied to the second electrode, the controller obtains an ion plasma frequency for a specific type of ion based on the measurement result, and the controller applies a high-frequency voltage of the ion plasma frequency to the plasma by setting the frequency of the high-frequency power supplied from the second high-frequency power supply as the ion plasma frequency.

### CROSS-REFERENCE TO RELATED APPLICATIONS

This application is a bypass continuation application of International Application No. PCT/JP2023/031707 having an international filing date of Aug. 31, 2023 and designating the United States, the International Application being based upon and claiming the benefit of priority from Japanese Patent Application No. 2022-163133 filed on Oct. 11, 2022, the entire contents of which are incorporated herein by reference.

### TECHNICAL FIELD

The present disclosure relates to a plasma processing apparatus and a plasma processing method.

### BACKGROUND

Conventionally, there is known a plasma processing apparatus capable of adjusting the energy of ions contained in plasma (see, for example, Japanese Laid-open Patent Publication No. 2020-155387). This plasma processing apparatus includes a processing chamber, and a partition plate that divides an inner space of the processing chamber into a reaction chamber in which a wafer is accommodated and a plasma generation chamber in which plasma is generated. Further, a plate electrode is provided on a surface of the partition plate that faces the plasma generation chamber, and an upper electrode is provided in the plasma generation chamber to face the plate electrode. Radicals or ions contained in the plasma generated in the plasma generation chamber pass through a plurality of through-holes in the partition plate to reach the wafer in the reaction chamber.

In this plasma processing apparatus, when plasma is generated, a high-frequency power of a tailored voltage waveform (TVW), which is obtained by phase-controlling and superimposing a plurality of high-frequency powers, is supplied to any one of the plate electrode and the upper electrode. Further, by controlling the TVW high-frequency power, the thickness of the plasma sheath generated in the plasma generation chamber is controlled. Here, when the thickness of the plasma sheath is changed, the acceleration of charged particles such as electrons and ions in the plasma can be changed. As a result, the energy of the ions contained in the plasma can be adjusted.

### SUMMARY

The technique of the present disclosure adjusts the energy of only specific types of ions contained in plasma.

According to an exemplary embodiment, a plasma processing apparatus is provided. The plasma processing apparatus for performing plasma processing on a substrate, comprising: a processing chamber configured to accommodate the substrate; a gas supply part configured to supply a processing gas into the processing chamber; a first electrode and a second electrode facing each other inside the processing chamber; a first high-frequency power supply configured to supply a high-frequency power to the first electrode, and a second high-frequency power supply configured to supply a high-frequency power to the second electrode; a sensor part configured to measure a state of plasma generated in the processing chamber; and a controller, wherein the first electrode applies a high-frequency voltage into the processing chamber to generate the plasma from the processing gas, the second high-frequency power supply is a broadband power supply and is capable of arbitrarily setting a frequency of the high-frequency power supplied to the second electrode, the controller obtains an ion plasma frequency for a specific type of ion based on a measurement result of the sensor part, and the controller applies a high-frequency voltage of the ion plasma frequency from the second electrode to the plasma by setting the frequency of the high-frequency power supplied from the second high-frequency power supply to the second electrode as the ion plasma frequency.

### BRIEF DESCRIPTION OF THE DRAWINGS

FIG. 1 is a cross-sectional view schematically showing a configuration of a plasma processing apparatus according to an embodiment of the present disclosure.

FIG. 2 is a graph showing the relationship between a frequency of a high-frequency power to be supplied and transmission characteristics of plasma.

FIG. 3 is a partial cross-sectional view for explaining in detail a configuration of an intermediate electrode of the plasma processing apparatus of FIG. 1.

FIG. 4A is a diagram for explaining an example of film formation performed in the plasma processing apparatus of FIG. 1.

FIG. 4B is a diagram for explaining an example of film formation performed in the plasma processing apparatus of FIG. 1.

FIG. 5A is a cross-sectional view schematically showing a configuration of a modification of the plasma processing apparatus of FIG. 1.

FIG. 5B is a cross-sectional view schematically showing a configuration of a modification of the plasma processing apparatus of FIG. 1.

### DETAILED DESCRIPTION

Generally, a processing gas for generating plasma may contain a plurality of components, and the plasma generated at the time contains a plurality of ions. On the other hand, depending on plasma processing, it may be desired to actively allow only specific type(s) of ions to reach the wafer, rather than multiple types of ions. For example, it may be desired to actively form a film containing a large amount of components generated by the reaction with specific types of ions. In this case, it is necessary to selectively increase the energy of only specific types of ions.

However, in the plasma processing apparatus according to the technique of the above-described Japanese Laid-open Patent Publication No. 2020-155387, the acceleration of all types of ions in the plasma is changed by the change of the thickness of the plasma sheath, so that it is difficult to change the energy of only specific types of ions.

Hence, in the technique of the present disclosure, the state of plasma generated in the processing chamber is measured, and the ion plasma frequency for specific types of ions is obtained based on the measured state of the plasma. Then, a high-frequency voltage of the corresponding ion plasma frequency is applied into the processing chamber.

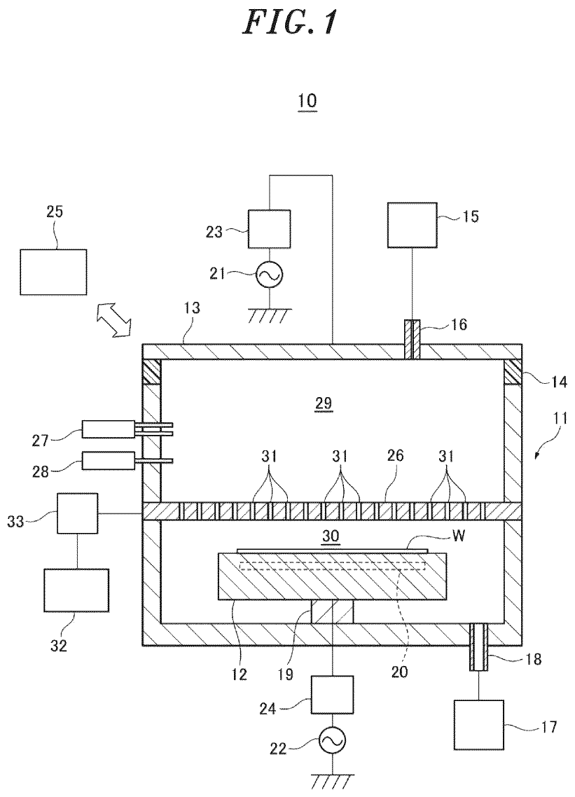

Hereinafter, an embodiment of the technique of the present disclosure will be described with reference to the accompanying drawings. FIG. 1 is a cross-sectional view schematically showing a configuration of a plasma processing apparatus as an embodiment of the technique of the present disclosure.

In FIG. 1, a plasma processing apparatus 10 is a capacitively coupled plasma (CCP) type plasma processing apparatus, and includes a substantially cylindrical processing chamber 11 having an upper opening, and a substrate placing table 12 provided at the bottom portion in the processing chamber 11. In the plasma processing apparatus 10, a wafer W (substrate) is accommodated in the processing chamber 11 and placed on the substrate placing table 12.

The processing chamber 11 is grounded, and the inner wall of the processing chamber 11 is covered with a thermal spray coating film made of a plasma-resistant material, for example, yttria. The upper opening of the processing chamber 11 is covered with an upper electrode 13 (first electrode) formed in a substantially disc shape. The upper electrode 13 is made of a conductive metal, for example, nickel or the like. The upper electrode 13 faces the inside of the processing chamber 11, and is electrically insulated from the processing chamber 11 while being supported by the sidewall of the processing chamber 11 via an insulating member 14.

Further, the plasma processing apparatus 10 includes a gas supply part 15. The gas supply part 15 is connected to the upper electrode 13 through a gas supply line 16, and supplies a processing gas into the processing chamber 11. In addition, in order to facilitate the diffusion of the processing gas in the processing chamber 11 when the processing gas is supplied, the gas supply line 16 may be branched into a plurality of supply lines to supply the processing gas from each part of the upper electrode 13 into the processing chamber 11. Further, in order to increase the uniformity of distribution of the processing gas in the processing chamber 11, a gas diffusion space may be provided in the upper electrode 13, and the processing gas may be supplied from the gas supply part 15 to the gas diffusion space. In this case, the processing gas diffuses in the gas diffusion space, and then is introduced into the processing chamber 11 through a plurality of communication holes that communicate the gas diffusion space and the inside of the processing chamber 11.

Further, in the plasma processing apparatus 10, an exhaust device 17 that exhausts air and a processing gas in the processing chamber 11 is connected to the bottom portion of the processing chamber 11 through an exhaust line 18. The exhaust device 17 exhausts air in the processing chamber 11 to reduce the pressure in the processing chamber 11 to a predetermined vacuum level.

The substrate placing table 12 has a substantially disc shape, and is made of a conductive metal such as nickel or the like. The substrate placing table 12 is supported from the bottom portion of the processing chamber 11 by a support member 19. Further, the substrate placing table 12 has therein a heater 20 and a coolant channel (not shown). The heater 20 heats the wafer W placed on the substrate placing table 12, and the coolant channel cools the wafer W by circulating a coolant cooled by a chiller unit (not shown). Accordingly, the temperature of the wafer W placed on the substrate placing table 12 is maintained at a desired temperature. Further, in order to improve the heat transfer efficiency between the substrate placing table 12 and the wafer W, the substrate placing table 12 is provided with an electrostatic chuck (not shown) for electrostatically attracting the wafer W and a heat transfer gas supply part (not shown) for supplying a heat transfer gas to the gap between the wafer W and the substrate placing table 12.

Further, the plasma processing apparatus 10 includes an upper high-frequency power supply 21 (first high-frequency power supply) and a lower high-frequency power supply 22. The upper high-frequency power supply 21 is connected to the upper electrode 13 via a matching device 23, and the lower high-frequency power supply 22 is connected to the substrate placing table 12 via a matching device 24. The upper high-frequency power supply 21 supplies a high-frequency power of a relatively high-frequency, e.g., a single frequency within the range of 50 KHz to 220 MHz, to the upper electrode 13. The lower high-frequency power supply 22 supplies a high-frequency power of a relatively low frequency, for example, 3.2 MHZ, to the substrate placing table 12. The matching device 23 matches the load impedance to the internal impedance of the upper high-frequency power supply 21 to suppress the reflection of the high-frequency power from the upper electrode 13. The matching device 24 matches the load impedance to the internal impedance of the lower high-frequency power supply 22 to suppress the reflection of the high-frequency power from the substrate placing table 12.

The upper electrode 13 applies a relatively high-frequency voltage into the processing chamber 11 due to the supplied high-frequency power. In this case, the processing gas supplied into the depressurized processing chamber 11 is excited, and plasma is generated from the processing gas. A bias voltage due to the supplied high-frequency power is generated at the substrate placing table 12, and the bias voltage attracts charged particles such as electrons and ions in the plasma to the wafer W placed on the substrate placing table 12. As a result, the wafer W is subjected to plasma processing, such as film formation or etching.

Further, the plasma processing apparatus 10 includes a controller 25. The controller 25 has a memory and a processor, and the processor reads and executes a program or a recipe stored in the memory to control the operations of individual components of the plasma processing apparatus 10. In the present embodiment, the controller 25 controls the operations of the individual components of the plasma processing apparatus 10 so that the film formation or the etching is performed on the wafer W by plasma.

Each of multiple types of ions in the plasma has a characteristic frequency referred to as an ion plasma frequency. When a high-frequency voltage of the ion plasma frequency is applied, the ion corresponding to the ion plasma frequency resonates and increases in energy, whereas other ions that do not correspond to the ion plasma frequency do not resonate and do not increase in energy. Therefore, by applying a high-frequency voltage of an ion plasma frequency corresponding to a specific type of ion to the plasma, it is possible to selectively increase only the energy of a specific type of ion.

Therefore, in order to apply a high-frequency voltage of an ion plasma frequency corresponding to a specific type of ion to the plasma, the plasma processing apparatus 10 includes an intermediate electrode 26 (second electrode), a network analyzer (NWA) 27, and a Langmuir probe 28. The NWA 27 and the Langmuir probe 28 correspond to a sensor part.

The intermediate electrode 26 is disposed between the upper electrode 13 and the substrate placing table 12 in the processing chamber 11, and divides the inside of the processing chamber 11 into a plasma generation chamber 29 and a reaction chamber 30. The intermediate electrode 26 is formed in a substantially disc shape, and is located to be substantially parallel to the upper electrode 13 and the substrate placing table 12. The space between the upper electrode 13 and the intermediate electrode 26 corresponds to the plasma generation chamber 29, and the space between the intermediate electrode 26 and the substrate placing table 12 corresponds to the reaction chamber 30.

As will be described later, the potential of the surface of the intermediate electrode 26 is maintained at the ground potential, so that the high-frequency voltage from the upper electrode 13 is applied only to the plasma generation chamber 29. Therefore, plasma is generated from the processing gas in the plasma generation chamber 29. Further, the intermediate electrode 26 is a matrix shower electrode having a plurality of through-holes 31. Since the through-holes 31 communicate the plasma generation chamber 29 and the reaction chamber 30, the plasma generated in the plasma generation chamber 29 enters the reaction chamber 30 through the through-holes 31, and reaches the wafer W placed on the substrate placing table 12.

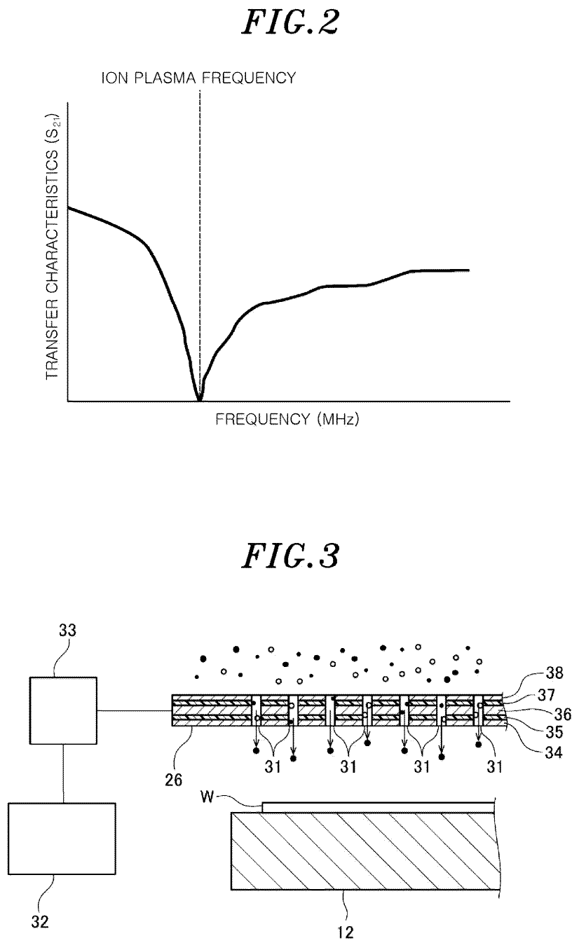

The NWA 27 is a sensor that measures the frequency characteristics, e.g., transfer characteristic S₂₁, of the plasma generated in the plasma generation chamber 29. Here, since a specific type of ion resonate at the ion plasma frequency thereof and absorb a large amount of high-frequency power as energy, it is expected that the transfer characteristic S₂₁ is minimized at the ion plasma frequency, as shown in FIG. 2. Therefore, in the plasma processing apparatus 10, the controller 25 obtains the frequency (hereinafter, referred to as “specific ion plasma frequency”) of the high-frequency power at which the transfer characteristic S₂₁ measured by the NWA 27 are minimized as the ion plasma frequency for a specific type of ion.

Further, the processing gas (hereinafter, referred to as “actual processing gas”) used in the actual plasma processing contains a plurality of components, so that the generated plasma may contain other types of ions as well as a specific type of ion. Therefore, even if the transfer characteristic S₂₁ of the plasma is measured by the NWA 27, it is assumed that a plurality of frequencies at which the transfer characteristic S₂₁ are minimized are measured multiple times to correspond to the respective types of ions, and it is difficult to identify the specific ion plasma frequency. Therefore, before the actual plasma processing is performed, plasma may be generated under the same conditions as those of the actual plasma processing from a single gas of a specific component with the same number of moles as the number of moles of a component (hereinafter, referred to as “specific component”) corresponding to the specific type of ion in the processing gas. In this case, the ions contained in the generated plasma are only a specific type of ion, and the frequency at which the transfer characteristic S₂₁ measured by the NWA 27 is minimized is considered as the specific ion plasma frequency. By using this method, the specific ion plasma frequency is obtained in the plasma processing apparatus 10.

As can be seen from the following Eq. (1), the ion plasma frequency depends on the ion density. Further, in the above-described method using a single gas, the ion density of a specific type of ion may be different from the ion density of the same specific type of ion generated from the actual processing gas. Therefore, the specific ion plasma frequency obtained by the above-described method using a single gas may be different from the specific ion plasma frequency in the case of using the actual processing gas. Hence, in order to obtain the specific ion plasma frequency more accurately, a technique for changing a single gas to the actual processing gas while observing the frequency at which the transfer characteristic S₂₁ is minimized may be considered. Specifically, first, the frequency at which the transfer characteristic S₂₁ is minimized in the above-described method using a single gas is considered. Then, the gas supplied by the gas supply part 15 is changed from the single gas to the actual processing gas. In this case, the frequency at which the transfer characteristic S₂₁ is minimized changes with the change in the ion density of a specific type of ion, and the frequency at which the transfer characteristic S₂₁ is minimized is tracked using the graph in FIG. 2, for example. Then, the frequency at which the transfer characteristic S₂₁ is minimized when the supplied gas is completely changed to the actual processing gas is obtained as the specific ion plasma frequency.

The Langmuir probe 28 measures various parameters of the plasma generated in the plasma generation chamber 29, such as a plasma potential, an electron (ion) density, and a plasma density. The ion plasma frequency of specific types of ions is calculated by the following Eq. (1).

$$[ Eq . ( 1 ) ]$$

$${f}_{pi} = \frac{\sqrt{{n}_{i} {Ze}^{2} / {ε}_{0} {M}_{i}}}{2 π} \qquad ( 1 )$$

Here, fₚᵢ is an ion plasma frequency, nᵢ is an ion density, Z is a valence, e is an elementary charge, so is a dielectric constant of plasma, and Mᵢ is an ion mass. Further, the valence and the ion mass are values specific to a specific type of ion, and the dielectric constant of the plasma is considered to be the dielectric constant of a vacuum, so that these parameters are known values. Therefore, the controller 25 obtains the specific ion plasma frequency according to the above Eq. (1) based on the ion density measured by the Langmuir probe 28, the known dielectric constant of the plasma, and the valence and the ion mass of the specific type of ion.

Further, as described above, the plasma generated from the actual processing gas may contain other types of ions as well as a specific type of ion. Therefore, to be strict, the ion density measured by the Langmuir probe 28 is the density of other types of ions as well as the density of a specific type of ion. Therefore, the controller 25 converts the ion density measured by the Langmuir probe 28 into the ion density of the specific type of ion based on the partial pressure and molar ratio of the specific component in the processing gas. Then, the specific ion plasma frequency is obtained by using the ion density of the specific type of ion converted in the calculation of the ion plasma frequency using the above Eq. (1).

Further, similarly to the method of obtaining the ion plasma frequency by the NWA 27, before the actual plasma processing is performed, plasma may be generated under the same conditions as those of the actual plasma processing from a single gas of the specific component with the same number of moles as the number of moles of the specific component in the processing gas. In this case, the ion density measured by the Langmuir probe 28 may be used as the ion density of the specific type of ion to obtain the specific ion plasma frequency.

Further, the plasma processing apparatus 10 includes a variable high-frequency power supply 32 (second high-frequency power supply), which is connected to the intermediate electrode 26 via a matching device 33. The variable high-frequency power supply 32 is a wideband power supply, and the frequency of the high-frequency power supplied to the intermediate electrode 26 can be set arbitrarily. Further, the matching device 33 matches the load impedance to the internal impedance of the variable high-frequency power supply 32 to suppress the reflection of the high-frequency power from the intermediate electrode 26. The intermediate electrode 26 applies a high-frequency voltage of a desired frequency into the processing chamber 11 due to the supplied high-frequency power.

In the plasma processing apparatus 10, the controller 25 sets the frequency of the high-frequency power supplied from the variable high-frequency power supply 32 to the intermediate electrode 26 to a specific ion plasma frequency. Accordingly, a high-frequency voltage of a specific ion plasma frequency is applied from the intermediate electrode 26 to the plasma in the processing chamber 11, thereby selectively increasing only the energy of a specific type of ion in the plasma. In this case, a specific type of ion with increased energy also have increased kinetic energy, and thus move more actively than other types of ions. As a result, the specific type of ion actively reaches the wafer. Accordingly, in the film forming process, a film (hereinafter, referred to as “specific component film”) containing a large amount of components generated by the reaction with a specific type of ion can be actively formed on the wafer W. Further, in the etching process, a film of a component that reacts with specific types of ions can be actively etched on the wafer W.

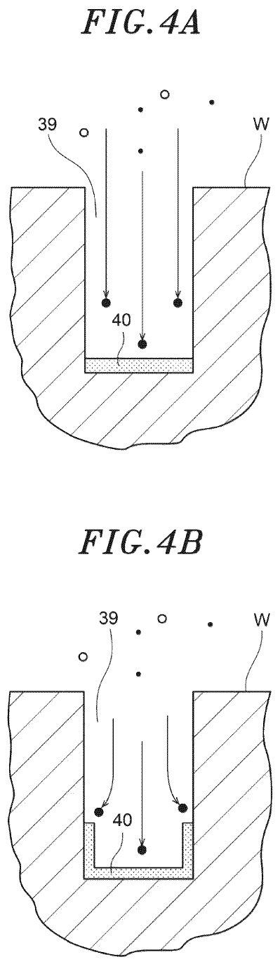

FIG. 3 is a partial cross-sectional view for explaining in detail the configuration of the intermediate electrode 26 of the plasma processing apparatus 10. The intermediate electrode 26 is an electrode having a laminated structure. In the intermediate electrode 26, as shown in FIG. 3, a lower ground electrode 34 (first ground electrode), a lower insulating layer 35 (first insulating layer), a conductive plate 36 (conductive layer), an upper insulating layer 37 (second insulating layer), and an upper ground electrode 38 (second ground electrode) are stacked in this order from the bottom. The lower ground electrode 34 faces the wafer W placed on the substrate placing table 12, and is maintained at a ground potential. The upper ground electrode 38 faces the upper electrode 13, and is maintained at a ground potential.

The variable high-frequency power supply 32 is connected to the conductive plate 36 of the intermediate electrode 26, and supplies the high-frequency power of the specific ion plasma frequency to the conductive plate 36. In this case, the high-frequency voltage of the specific ion plasma frequency is applied to the vicinity of the conductive plate 36.

Since, however, the upper side and the lower side of the conductive plate 36 are covered by the lower ground electrode 34 and the upper ground electrode 38, respectively, the high-frequency voltage of the specific ion plasma frequency is not actually applied to the plasma in the plasma generation chamber 29 or the reaction chamber 30. Therefore, it is possible to suppress the influence of the high-frequency voltage of the specific ion plasma frequency on the generation of plasma in the plasma generation chamber 29. It is also possible to suppress the influence of the high-frequency voltage of the specific ion plasma frequency on the bias voltage generated at the substrate placing table 12.

Since the conductive plate 36 is exposed to the through-holes 31 of the intermediate electrode 26, the high-frequency voltage of the specific ion plasma frequency is applied to the plasma that has entered the through-holes 31. In this case, the energy of the specific type of ion that have entered the through-holes 31 is increased and the specific ions are accelerated, but the energy of other ions and electrons that have entered the through-holes 31 is not increased and they are not accelerated. Therefore, the intermediate electrode 26 functions as a certain type of ion accelerator that selects the specific type of ion and accelerates them toward the wafer Won the substrate placing table 12. In the drawing, black circles indicate specific type of ion, white circles indicate other ions, and dots indicate electrons.

In the intermediate electrode 26, the upper side and the lower side of the conductive plate 36 are covered with the lower ground electrode 34 and the upper ground electrode 38, respectively. However, if it is acceptable that the high-frequency voltage of the specific ion plasma frequency slightly affects the generation of plasma and the bias voltage, the lower ground electrode 34 and the upper ground electrode 38 may not be provided. However, even in this case, the upper side and the lower side of the conductive plate 36 are covered with the lower insulating layer 35 and the upper insulating layer 37, respectively.

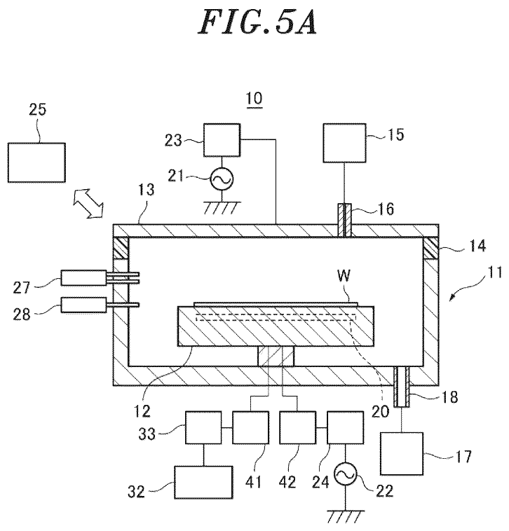

FIGS. 4A and 4B are diagrams for explaining an example of a film forming process performed in the plasma processing apparatus 10. In FIGS. 4A and 4B, a process of forming a specific component film on an inner surface of a trench 39 formed in the wafer W is shown. Also in FIGS. 4A and 4B, black circles indicate a specific type of ion, white circles indicate other types of ions, and dots indicate electrons.

As described above, in the plasma processing apparatus 10, when a specific component film is formed, the controller 25 applies a high-frequency voltage of a specific ion plasma frequency from the intermediate electrode 26 to the plasma. In this case, the energy of a specific type of ion is increased, and the specific type of ion is accelerated toward the wafer W on the substrate placing table 12. Further, the increase in the energy of a specific type of ion depends on the strength of the high-frequency voltage of the specific ion plasma frequency, i.e., the magnitude of the high-frequency power of the specific ion plasma frequency supplied to the intermediate electrode 26. For example, when the high-frequency power of the specific ion plasma frequency supplied to the intermediate electrode 26 is increased, the increase in the energy of a specific type of ion increases, and the kinetic energy also increases considerably, which results in an increase in the reaching distance of a specific type of ion. On the other hand, when the high-frequency power of the specific ion plasma frequency supplied to the intermediate electrode 26 is decreased, the increase in the energy of a specific type of ion decreases, and the kinetic energy does not increase considerably, which results in a decrease in the reaching distance of a specific type of ion.

Therefore, in the plasma processing apparatus 10, the magnitude of the high-frequency power of the specific ion plasma frequency supplied to the intermediate electrode 26 is changed/adjusted according to types of film formation. For example, when the high-frequency power of the specific ion plasma frequency supplied to the intermediate electrode 26 is increased, the kinetic energy of the specific type of ion increases significantly, and the reaching distance of the specific type of ion increases. As a result, as shown in FIG. 4A, most of the specific type of ion reaches the bottom portion of the trench 39, and a specific component film 40 is formed only on the bottom portion of the trench 39. In other words, the anisotropic specific component film 40 is formed. Further, when the high-frequency power of the specific ion plasma frequency supplied to the intermediate electrode 26 is decreased, the increase in the kinetic energy of a specific type of ion decreases, and the reaching distance of the specific type of ion decreases. As a result, as shown in FIG. 4B, a certain amount of a specific type of ion does not reach the bottom portion of the trench 39, and is attached to the side surface of the trench 39. Hence, the specific component film 40 is formed on the side surface of the trench 39 as well as on the bottom portion of the trench 39. In other words, the isotropic specific component film 40 is formed.

Although not shown in the drawing, in the etching process, when the high-frequency power of the specific ion plasma frequency supplied to the intermediate electrode 26 is increased, most of a specific type of ion reach the bottom portion of the trench 39, and anisotropic etching is realized. Further, when the high-frequency power of the specific ion plasma frequency supplied to the intermediate electrode 26 is decreased, the amount of a specific type of ion that reach the side surface of the trench 39 without reaching the bottom portion of the trench 39 increases, and isotropic etching is realized.

In other words, in the plasma processing apparatus 10, when anisotropic plasma processing is performed on the wafer W using a specific type of ion, it is preferable to increase the high-frequency power of the specific ion plasma frequency supplied from the variable high-frequency power supply 32 to the intermediate electrode 26. Further, when isotropic plasma processing is performed on the wafer W using a specific type of ion, it is preferable to decrease the high-frequency power of the specific ion plasma frequency supplied from the variable high-frequency power supply 32 to the intermediate electrode 26.

In accordance with the present embodiment, the specific ion plasma frequency is obtained based on the frequency characteristics and parameters of the plasma generated in the plasma generation chamber 29 of the plasma processing apparatus 10. Further, the high-frequency voltage of the acquired specific ion plasma frequency is applied to the plasma. Accordingly, it is possible to adjust the energy of only specific type of ion, rather than the overall energy of multiple types of ions contained in the plasma.

Although the preferred embodiments of the present disclosure have been described above, the present disclosure is not limited to the above-described embodiment, and various modifications and changes can be made within the scope of the gist thereof.

For example, in the above-described plasma processing apparatus 10, the controller 25 controls the variable high-frequency power supply 32 to supply the high-frequency power of one specific ion plasma frequency to the intermediate electrode 26, thereby increasing only the energy of one specific type of ion. However, the controller 25 may acquire a plurality of specific ion plasma frequencies using the NWA 27 or the Langmuir probe 28, and may control the variable high-frequency power supply 32 to supply the high-frequency power of each specific ion plasma frequency to the intermediate electrode 26. In this case, the controller 25 sets the frequency of the high-frequency power supplied by the variable high-frequency power supply 32 as the acquired multiple specific ion plasma frequencies, and controls the variable high-frequency power supply 32 to supply the multiple specific ion plasma frequencies to the intermediate electrode 26 in a superimposed manner. Accordingly, the multiple specific ion plasma frequency high-frequency voltages can be applied from the intermediate electrode 26 to the plasma in a superimposed manner, thereby increasing the energy of multiple specific types of ions. As a result, the wafer W can be subjected to plasma processing that actively uses multiple specific types of ions.

Further, the controller 25 may set the timings of supplying the high-frequency powers of multiple specific ion plasma frequencies from the variable high-frequency power supply 32 to the intermediate electrode 26 to be different from each other. In this case, the high-frequency voltages of multiple specific ion plasma frequency frequencies can be applied from the intermediate electrode 26 to plasma at different timings. Accordingly, the timings of plasma processing using respective specific types of ions may be different from each other. In this case, in a film forming process, for example, a film in which the main component changes in the thickness direction can be formed.

The plasma processing apparatus 10 described above includes the NWA 27 and the Langmuir probe 28 to obtain the specific ion plasma frequency, but the controller 25 can obtain the specific ion plasma frequency using the measurement results of any one of them. Therefore, the plasma processing apparatus 10 may include any one of the Langmuir probe 28 and the NWA 27.

Further, in the plasma processing apparatus 10, the lower high-frequency power supply 22 is connected to the substrate placing table 12, and a bias voltage is generated at the substrate placing table 12. Since, however, the bias voltage may not be necessary depending on plasma processing, the lower high-frequency power supply 22 may not be connected to the substrate placing table 12.

Further, in the plasma processing apparatus 10, the intermediate electrode 26 separate from the upper electrode 13 and the substrate placing table 12 is provided, and the variable high-frequency power supply 32 is connected to the intermediate electrode 26. However, the intermediate electrode 26 may not be provided, and the variable high-frequency power supply 32 may be connected to the upper electrode 13 and the substrate placing table 12.

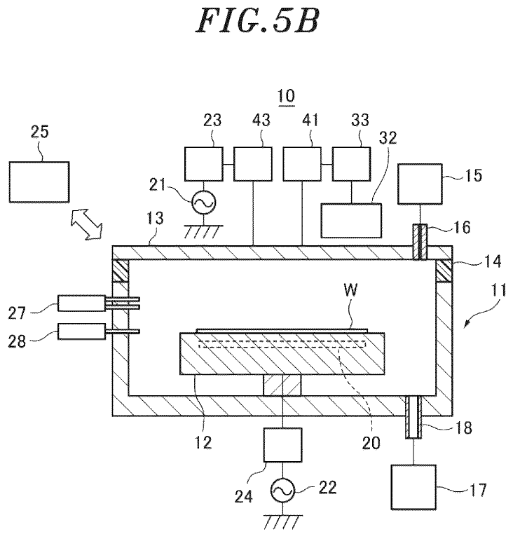

For example, as shown in FIG. 5A, the variable high-frequency power supply 32 may be connected to the substrate placing table 12. In this case, the intermediate electrode 26 is substantially integrated with the substrate placing table 12, and the substrate placing table 12 applies the specific ion plasma frequency to the plasma. In this case, the variable high-frequency power supply 32 is connected to the substrate placing table 12 through a band end filter (BEF) 41 as well as the matching device 33 so that the high-frequency power supplied by the lower high-frequency power supply 22 does not flow into the variable high-frequency power supply 32. Further, the lower high-frequency power supply 22 is also connected to the substrate placing table 12 through a BEF 42 as well as the matching device 24 so that the high-frequency power supplied by the variable high-frequency power supply 32 does not flow into the lower high-frequency power supply 22.

Further, as shown in FIG. 5B, the variable high-frequency power supply 32 may be connected to the upper electrode 13. In this case, the intermediate electrode 26 is substantially integrated with the upper electrode 13, and the upper electrode 13 applies the specific ion plasma frequency to the plasma. In this case, the variable high-frequency power supply 32 is connected to the upper electrode 13 through the BEF 41 as well as the matching device 33 to prevent the high-frequency power supplied by the upper high-frequency power supply 21 from flowing into the variable high-frequency power supply 32. The variable high-frequency power supply 21 is also connected to the upper electrode 13 through a BEF 43 as well as the matching device 23 so that the high-frequency power supplied by the variable high-frequency power supply 32 does not flow into the upper high-frequency power supply 21.

This application claims priority to Japanese Patent Application No. 2022-163133 filed on Oct. 11, 2022, the entire contents of which are incorporated herein by reference.

1. A plasma processing apparatus for performing plasma processing on a substrate, comprising:
a processing chamber configured to accommodate the substrate;
a gas supply part configured to supply a processing gas into the processing chamber;
a first electrode and a second electrode facing each other inside the processing chamber;
a first high-frequency power supply configured to supply a high-frequency power to the first electrode, and a second high-frequency power supply configured to supply a high-frequency power to the second electrode;
a sensor part configured to measure a state of plasma generated in the processing chamber; and
a controller,
wherein the first electrode applies a high-frequency voltage into the processing chamber to generate the plasma from the processing gas,
the second high-frequency power supply is a broadband power supply and is capable of arbitrarily setting a frequency of the high-frequency power supplied to the second electrode,
the controller obtains an ion plasma frequency for a specific type of ion based on a measurement result of the sensor part, and
the controller applies a high-frequency voltage of the ion plasma frequency from the second electrode to the plasma by setting the frequency of the high-frequency power supplied from the second high-frequency power supply to the second electrode as the ion plasma frequency.

2. The plasma processing apparatus of claim 1, wherein the controller obtains multiple ion plasma frequencies for multiple specific types of ions based on the measurement result of the sensor part, and
the controller sets the frequency of the high-frequency power supplied from the second high-frequency power supply to the second electrode as the multiple ion plasma frequencies, and applies a high-frequency voltage of the multiple ion plasma frequencies from the second electrode to the plasma in a superimposed manner.

3. The plasma processing apparatus of claim 1, wherein the controller obtains multiple ion plasma frequencies for multiple specific types of ions based on the measurement result of the sensor part, and
the controller sets the frequency of the high-frequency power supplied from the second high-frequency power supply to the second electrode as the plurality of ion plasma frequencies, and applies high-frequency voltages of the plurality of ion plasma frequencies from the second electrode to the plasma at different timings.

4. The plasma processing apparatus of claim 1, wherein the controller changes a magnitude of the high-frequency power of the ion plasma frequency supplied from the second high-frequency power supply to the second electrode according to plasma processing performed on the substrate.

5. The plasma processing apparatus of claim 4, wherein the controller increases the high-frequency power of the ion plasma frequency supplied from the second high-frequency power supply to the second electrode when anisotropic plasma processing is performed on the substrate, and
the controller decreases the high-frequency power of the ion plasma frequency supplied from the second high-frequency power supply to the second electrode when isotropic plasma processing is performed on the substrate.

6. The plasma processing apparatus of claim 1, wherein the sensor part is a Langmuir probe, and
the controller obtains the ion plasma frequency for the specific type of ion based on parameters of the plasma measured by the Langmuir probe.

7. The plasma processing apparatus of claim 1, wherein the sensor part is a network analyzer, and
the controller obtains the ion plasma frequency for the specific type of ion as a frequency of a high-frequency voltage at which transmission characteristic of a frequency of the plasma measured by the network analyzer is minimized.

8. The plasma processing apparatus of claim 1, wherein the second electrode is a matrix shower electrode disposed in the processing chamber, and is positioned between the first electrode and the substrate, and
the plasma is generated in a space between the first electrode and the second electrode.

9. The plasma processing apparatus of claim 8, wherein the second electrode has a laminated structure in which a first ground electrode, a first insulating layer, a conductive layer, a second insulating layer, and a second ground electrode are stacked in this order, and
the second ground electrode faces the first electrode, and the first ground electrode faces the substrate.

10. The plasma processing apparatus of claim 1, wherein the second electrode is integrated with a substrate placing table on which the substrate is placed.

11. The plasma processing apparatus of claim 1, wherein the second electrode is integrated with the first electrode, which is disposed to face the substrate.

12. The plasma processing apparatus of claim 1, wherein the plasma processing is a film forming process or an etching process.

13. A plasma processing method for performing plasma processing on a substrate, comprising:
supplying a processing gas into a processing chamber accommodating the substrate, and applying a high-frequency voltage from a first electrode into the processing chamber to generate plasma from the processing gas;
measuring a state of the generated plasma;
obtaining an ion plasma frequency for a specific type of ion based on the measurement result of the state of the plasma; and
applying a high-frequency voltage of the ion plasma frequency to the plasma from a second electrode different from the first electrode.
